(19) United States
(12) Patent Application Publication
(10) Pub. No.: US 2017/0234573 A1
(43) Pub. Date: Aug. 17, 2017

(54) BAFFLE FOR DIRECTING AIR FLOW IN A RACK

(71) Applicant: Microsoft Technology Licensing, LLC, Redmond, WA (US)

(72) Inventors: Justin Clay Shaw, South Hill, VA (US); James Darrin Schroeder, San Antonio, TX (US)

(21) Appl. No.: 15/044,553

(22) Filed: Feb. 16, 2016

(51) Int. Cl. F24F 13/08; H05K 7/20

(52) U.S. Cl. CPC F24F 13/08; H05K 7/20836

(57) ABSTRACT

Aspects extend to a baffle for directing air flow in a rack. For example, a baffle can be used to prevent recirculation of air within an equipment rack. When installed in a rack, the baffle creates a tunnel that more efficiently directs cold (or cooler) air from a cold (or cool) aisle into the intake of components that span less than full width of the rack. The baffle reduces excess air from flowing from a cold (or cool) aisle to a hot (or warm) aisle without passing through media and/or cooling a piece of equipment. Preventing excess air from flowing from a cold (or cool) aisle to a hot (or warm) aisle increases cooling efficiency. Use of a baffle can also significantly reduce cold (or cooler) air flowing into hot (or warm) aisle containment and up through the plenum without passing through any media that requires the cooling. Thus, running speed of Air Handling Units (AHUs) can be reduced while maintaining a viable pressure.

### CROSS-REFERENCE TO RELATED APPLICATIONS

Not Applicable.

### BACKGROUND

### 1. Background and Relevant Art

Computer systems and related technology affect many aspects of society. Indeed, the computer system's ability to process information has transformed the way we live and work. More recently, computer systems have been coupled to one another and to other electronic devices to form both wired and wireless computer networks over which the computer systems and other electronic devices can transfer electronic data. Accordingly, the performance of many computing tasks is distributed across a number of different computer systems and/or a number of different computing environments. For example, distributed applications can have components at a number of different computer systems.

In many computing environments, multiple components are grouped together in an equipment rack. One or more equipment racks can be grouped in a common physical location in what is often referred to as a “data center”. Components in an equipment rack can include servers (e.g., “blades”), networking equipment (e.g., top-of-rack (TOR) switches), power supplies, etc. The components generate excess heat which, if not properly accounted for, can cause component operation to become unstable. Excess heat increases with more components and when multiple racks are placed in a closed room.

To dissipate heat, various techniques including HVAC and adiabatic cooling can be used. Equipment within each rack is installed such that each piece of equipment intakes air from one side of the rack and exhausts air to the other (opposite) side of the rack. In some data centers, equipment racks are arranged in rows. Each row has a cold aisle of air on one side (the intake side) and a hot aisle of air on the other side (the exhaust side). As such, cooler air is continual pulled from the cold aisle through the equipment. The air increases in temperature when going through the equipment and is exhausted into the host aisle. Cold aisles and hot aisles are separated from one another within a data center.

Some pieces of equipment within a rack can span from one side of the rack (e.g., cold aisle side) to the other side of the rack (e.g., hot aisle side). These pieces of equipment can be secured on both sides of the rack. Since these pieces of equipment span the rack, intakes can extended partial into or are essentially on the edge of the cold aisle. As such, it is relatively efficient and effective to cool these pieces of equipment pulling air from the cold aisle.

When a rack is not completely full vertically, blanking panels can be used to block air from the cold aisle from entering the rack. Use of blanking panels conserves resources since cooler air does not unnecessarily enter a rack.

There are also other pieces of equipment (e.g., TOR switches) that do not fully span from one side of a rack to the other side of the rack. These pieces of equipment are typically connected to a rack on the hot aisle side. Depending on length, intake for these other pieces of equipment are typically situated somewhere inside the rack and are thus further from the cold aisle. Since the intakes are further from the cold aisle, it is less efficient and effective to cool these other pieces of equipment.

Further, hot exhaust leaving some pieces of equipment in a rack can recirculate within the rack. The hot exhaust can rise and be sucked into the intake of other pieces of equipment in the rack.

Additionally, in some environments, (e.g., 1 or 2) blanking panels are left off the top of a rack to allow air to get to TORs (or other components) even though it mixes with the air from the exhaust. Leaving off the blanking panels results in a large open area in which cold air from the cold isle is able to flow through into the hot isle containment. The cold air can pass up through the plenum without passing through any media that requires the cooling. As such, Air Handling Units (AHUs) are run at a higher rate to maintain pressure. Running AHUs at a higher rate requires more power and thus costs more.

### BRIEF SUMMARY

Examples extend to a baffle for directing air flow in a rack. The baffle is included in a rack containing data center components. In one aspect, the baffle includes single piece. The baffle includes a first end (e.g., adjacent to a hot or warm aisle) configured for attachment to a first side surface of an equipment rack. The baffle also includes a second end (e.g., adjacent to a cold or cool aisle) configured for attachment to a second side surface of the equipment rack. The first side surface and second side surface arranged to form an accommodation room to accommodate equipment installed into the equipment rack.

A panel spans from the first end to the second end of the equipment rack. The panel is configured to separate the airflow to equipment above the panel in the accommodation room from the airflow to equipment below the panel in the accommodation room. The first end of the baffle a closed configuration to reduce airflow out of the accommodation room at the first end. The second end of the baffle is in an open configuration to permit air to flow into the accommodation room at the second end.

In another aspect, the baffle includes multiple pieces. A first component is configured for attachment to a first side (e.g., adjacent to a hot or warm aisle) surface of an equipment rack. A second component is configured for attachment to a second side (e.g., adjacent to a cold or cool aisle) surface of the equipment rack. The first side surface and second side surface arranged to form an accommodation room to accommodate equipment installed into the equipment rack.

The first component includes a first panel and a second panel. The first panel spans from the first side surface towards the second side surface to an intermediate location within the accommodation room. The second panel is essentially perpendicular to the first panel. The second panel is configured to block air from flowing directly out of the accommodation room at the first side surface.

The second component includes a third panel. The third panel spans from the second side surface towards the first side surface past the intermediate location to overlap with the first panel. As such, the baffle is configured to separate the airflow to equipment above the first panel and the third panel in the accommodation room from the airflow to equipment below the first panel and the third panel in the accommodation room.

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by practice. The features and advantages may be realized and obtained by means of the instruments and combinations particularly pointed out in the appended claims. These and other features and advantages will become more fully apparent from the following description and appended claims, or may be learned by practice as set forth hereinafter.

### BRIEF DESCRIPTION OF THE DRAWINGS

In order to describe the manner in which the above-recited and other advantages and features can be obtained, a more particular description will be rendered by reference to specific implementations thereof which are illustrated in the appended drawings. Understanding that these drawings depict only some implementations and are not therefore to be considered to be limiting of its scope, implementations will be described and explained with additional specificity and detail through the use of the accompanying drawings in which:

FIG. 1 illustrates a single component baffle.

FIG. 2 illustrates an example of a single component baffle installed in an equipment rack.

FIG. 3A illustrates components of a multi-component baffle.

FIG. 3B illustrates the components of the multi-component baffle connected to form the multi-component baffle.

FIG. 4 illustrates an example of a multi-component baffle installed in an equipment rack.

### DETAILED DESCRIPTION

Examples extend to a baffle for directing air flow in a rack. The baffle is included in a rack containing data center components. In one aspect, the baffle includes single piece. The baffle includes a first end (e.g., adjacent to a hot or warm aisle) configured for attachment to a first side surface of an equipment rack. The baffle also includes a second end (e.g., adjacent to a cold or cool aisle) configured for attachment to a second side surface of the equipment rack. The first side surface and second side surface arranged to form an accommodation room to accommodate equipment installed into the equipment rack.

A panel spans from the first end to the second end of the equipment rack. The panel is configured to separate the airflow to equipment above the panel in the accommodation room from the airflow to equipment below the panel in the accommodation room. The first end of the baffle a closed configuration to reduce airflow out of the accommodation room at the first end. The second end of the baffle is in an open configuration to permit air to flow into the accommodation room at the second end.

In another aspect, the baffle includes multiple pieces. A first component is configured for attachment to a first side (e.g., adjacent to a hot or warm aisle) surface of an equipment rack. A second component is configured for attachment to a second side (e.g., adjacent to a cold or cool aisle) surface of the equipment rack. The first side surface and second side surface arranged to form an accommodation room to accommodate equipment installed into the equipment rack.

The first component includes a first panel and a second panel. The first panel spans from the first side surface towards the second side surface to an intermediate location within the accommodation room. The second panel is essentially perpendicular to the first panel. The second panel is configured to block air from flowing directly out of the accommodation room at the first side surface.

The second component includes a third panel. The third panel spans from the second side surface towards the first side surface past the intermediate location to overlap with the first panel. As such, the baffle is configured to separate the airflow to equipment above the first panel and the third panel in the accommodation room from the airflow to equipment below the first panel and the third panel in the accommodation room.

In this description and the following claims, a “baffle” is defined as a component used to restrict or restrain airflow to prevent airflow in a particular direction.

In one aspect, one or more pluralities of racks are arranged in rows within a data center or other physical space. Each row of racks separates a cold (or cool) aisle from a hot (or warm) aisle. Air intakes for equipment in each rack are positioned to face the cold (or cool) aisle. Exhausts for equipment in each rack are positioned to face the hot (or warm) aisle. Different rows can pull cold or cooler air from a common cold or cooler aisle and/or can exhaust hot or warmer air to a common hot or warm aisle. Air in a cold or cool aisle can be maintained at a lower temperature than air in a hot or warm aisle.

Aspects of the invention include using a baffle to prevent recirculation of air within an equipment rack. When installed in a rack, the baffle creates a tunnel that more efficiently directs cold (or cooler) air from a cold (or cool) aisle into the intake of components, such as, for example, a Top-Of-Rack (TOR) switch, that span less than full width of the rack. The baffle significantly reduces excess air from flowing from a cold (or cool) aisle to a hot (or warm) aisle without passing through media and/or cooling a piece of equipment. Preventing excess air from flowing from a cold (or cool) aisle to a hot (or warm) aisle increases cooling efficiency.

Use of a baffle can also significantly reduce cold (or cooler) air flowing into a hot (or warm) aisle containment and up through the plenum without passing through any media that requires the cooling. As such, the running speed of Air Handling Units (AHUs) can be reduced while maintaining a viable pressure.

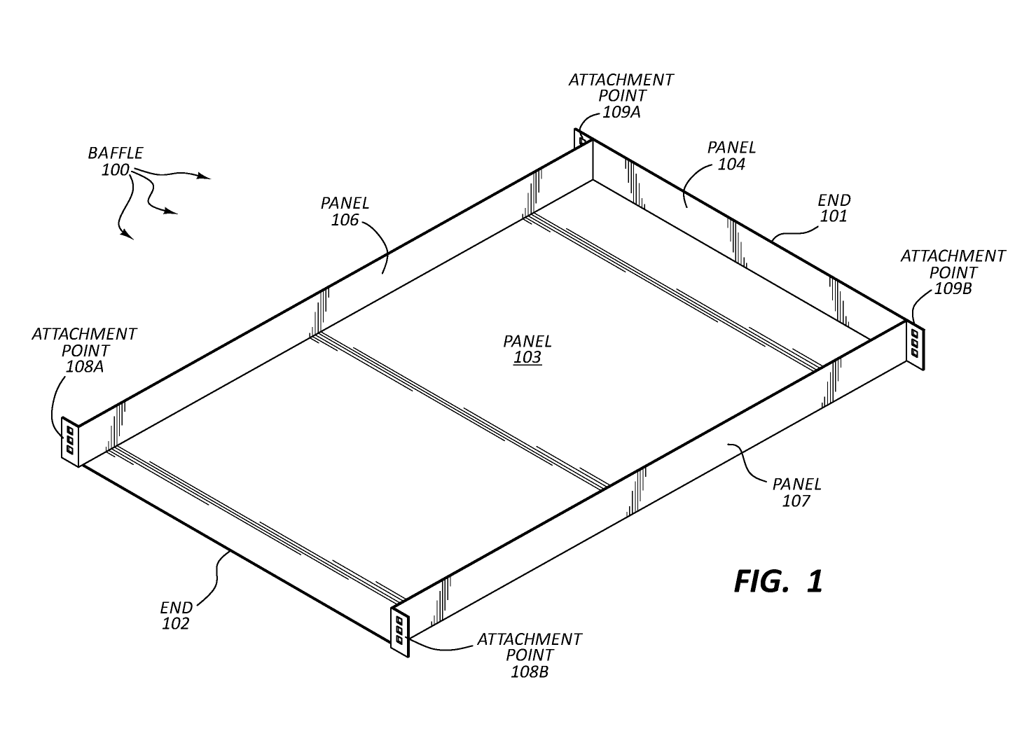

FIG. 1 illustrates a single component baffle 100. As depicted, baffle 100 includes panels 103, 104, 106, and 107. Attachment points 109A and 109B can be used to attach end 101 to one side (e.g., a hot or warm aisle side) of an equipment rack. Similarly, attachment points 108A and 108B can be used to attach end 102 to another side (e.g., a cold or cool aisle side) of an equipment rack. Attachment points 108A, 108B, 109A, and 109B, can be wings for attachment to a post (square-hole or unthreaded round-hole) of a rack (e.g., 19-inch rack or 23-inch rack). Baffle 100 (or other similar baffle) can be mounted under other equipment in a rack (e.g., a TOR) to direct cold (or cool) aisle air to air intakes of the equipment and to prevent recirculation of air within the rack.

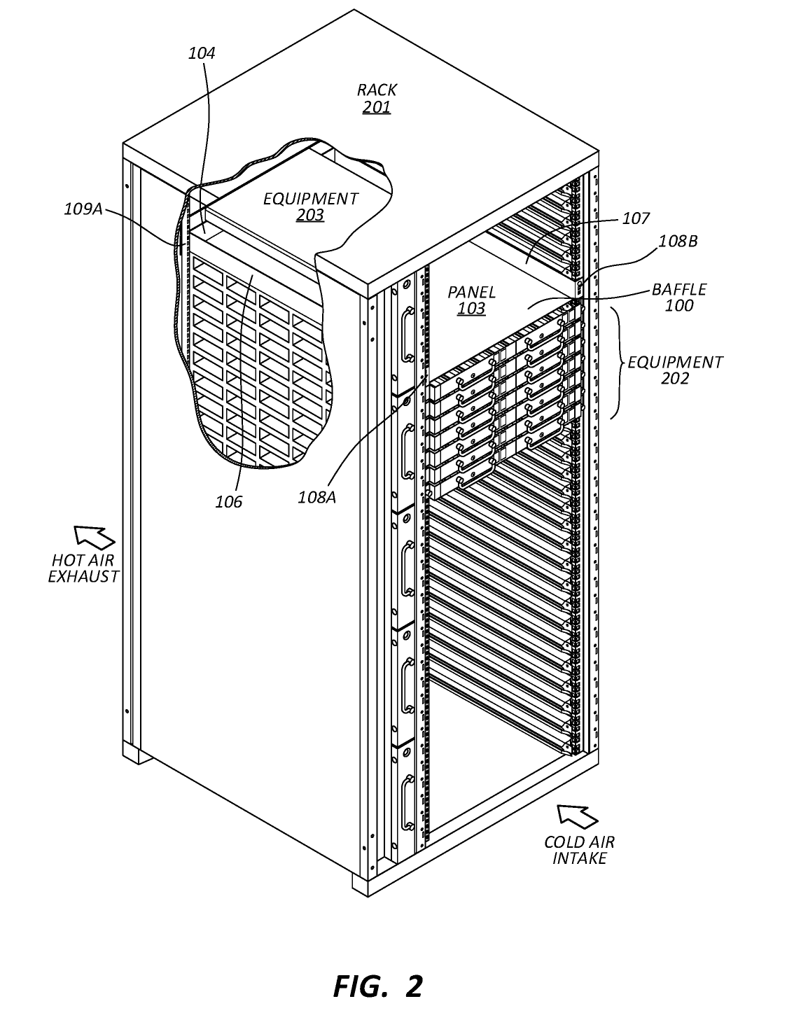

FIG. 2 illustrates an example of a baffle 100 installed in equipment rack 201. As depicted, baffle 100, equipment 202, and equipment 203 are accommodated inside rack 201. Baffle 100 is mounted to rack 201 using attachment points 108A, 108B, 109A, and 109B. Attachment points 108A are 108B attach baffle 100 to a cold (or cool) aisle side of rack 201. Attachment points 109A and 109B attach baffle 100 to a hot (or warm) aisle side of rack 201. The height of attachment points 108A, 108B, 109A, and 109B can be 1 Rack Unit or “1U” relative to server rack rails within rack 201. Within rack 201, baffle 100 prevents air below panel 103 from entering the air intakes of equipment 203. Baffle 100 also channels air from the cold (or cool) aisle into the air intakes of equipment 203.

Additional blanking panels (not shown) can be used to block the entry of air into portions of rack 201 above equipment 203. In other aspects, equipment 203 and baffle 100 are mounted nearer to the top of rack 201. For example, baffle 100 can be mounted within the top 4 U slots of rack 201. However, these additional panels are omitted in FIG. 2 and equipment 203 and baffle 100 are positioned lower in rack 201 to provide a clear view inside rack 201.

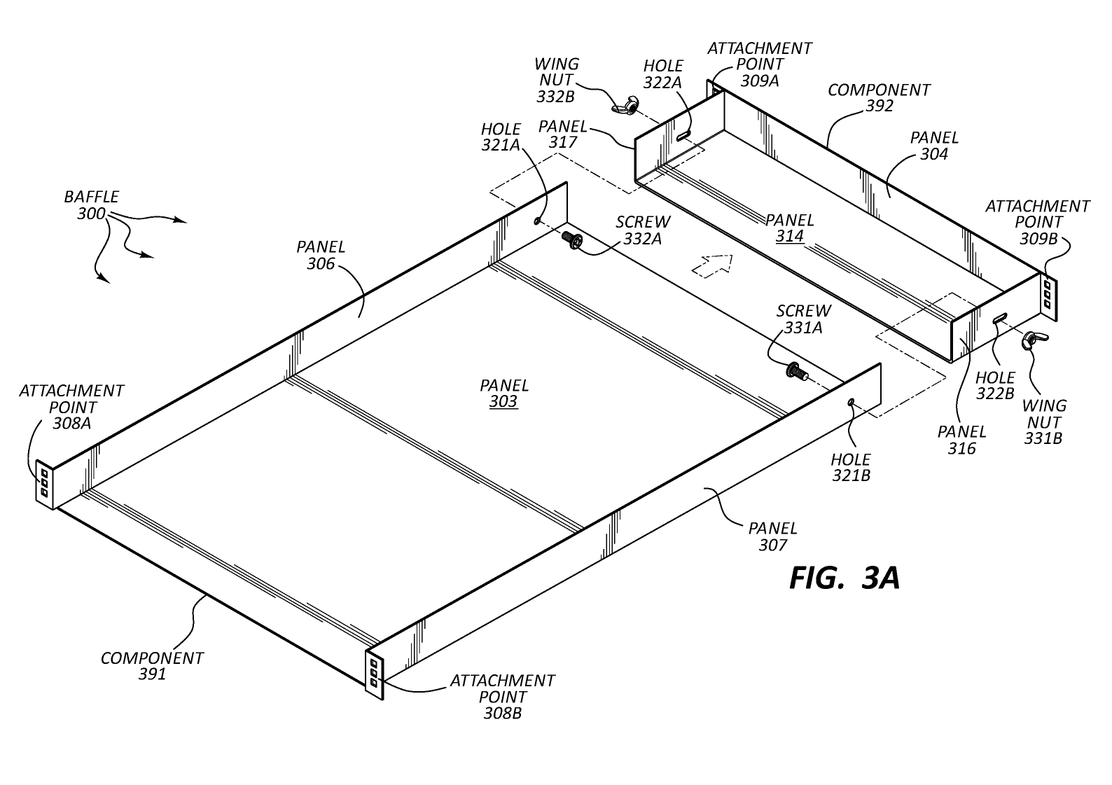

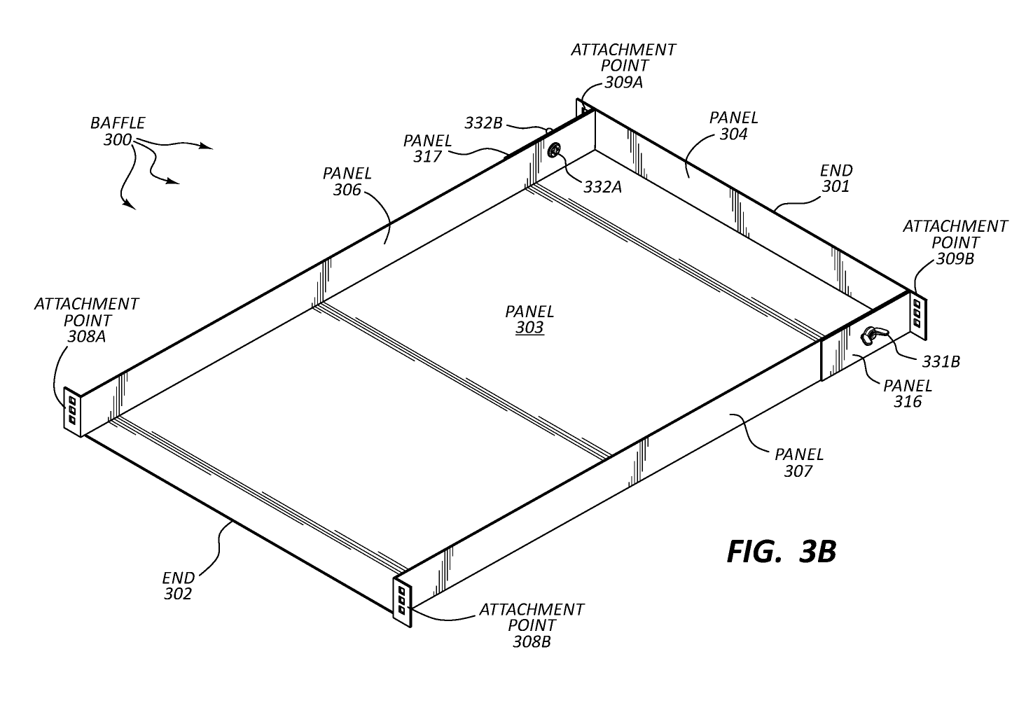

FIG. 3A illustrates components 391 and 391 of a multi-component baffle. Component 391 includes panels 303, 306, and 307 and attachment points 308A and 308B. Panels 306 and 307 include holes 32a and 321B respectively. Attachment points 308A and 308B can be used to component 391 to one side (e.g., a cold or cool aisle side) of an equipment rack.

Component 392 includes panels 304, 314, 316, and 317 and attachment points 309A and 309B. Panels 317 and 316 include holes 322A and 322B respectively. Attachment points 309A and 309B can be used to component 392 to another side (e.g., a hot or warm aisle side) of an equipment rack.

Component 392 can be marginally wider than the width of component 391 (at least at the end of component 391 that includes holes 321A and 321B). As such, component 391 can slide into component 392 (as indicated by the dashed arrow). Hole 321A can be aligned with hole 322A and hole 321B can be aligned with hole 322B. Screw 332A can be inserted through aligned holes 321A and 322A. Wingnut 332B can be screwed onto screw 332A to mechanically secure panel 306 and panel 317 to one another. Similarly, screw 331A can be inserted through aligned holes 321B and 322B. Wingnut 332B can be screwed onto screw 331A to mechanically secure panel 307 and panel 316 to one another.

FIG. 3B illustrates the components of 391 and 392 connected to another to form baffle 300. As depicted, panel 303 covers panel 314. However, depending on the position of holes 321A and 321B a portion of panel 314 may remain uncovered by panel 303. Also as depicted, panels 306 and 307 are inside of panels 317 and 316 respectively. Panels 306 and 317 are secured to one another with screw 332A and wingnut 332B. Panels 307 and 316 are secured to one another with screw 331A and wingnut 331B.

Attachment points 309A and 309B can be used to attach end 301 to one side (e.g., a hot or warm aisle side) of an equipment rack. Similarly, attachment points 308A and 308B can be used to attach end 302 to another side (e.g., a cold or cool aisle side) of an equipment rack. Attachment points 308A, 308B, 309A, and 309B, can be wings for attachment to a post (square-hole or unthreaded round-hole) of a rack (e.g., 19-inch rack or 23-inch rack). Baffle 300 (or other similar baffle) can be mounted under other equipment in a rack (e.g., a TOR) to direct cold (or cool) aisle air to air intakes of the equipment and to prevent recirculation of air within the rack.

In one aspect, components 391 and 392 are individually installed into an equipment rack and then connected to one another. For example, component 392 can be inserted into a rack from a hot (or warm) aisle side. Component 392 can be attached to rack rails on the hot (or warm) aisle side of the rack using attachment points 309A and 309B. Subsequently, component 391 can be inserted into the rack from the cold (or cool) aisle side. Component 391 can be inserted to line up hole 321A with hole 322A and line up hole 321B with hole 322B. Component 391 can be attached to the rack rails on the cold (or cool) aisle side of the rack using attachment points 308A and 308B. Screw 332A and wingnut 332B can be used to secure panels 306 and 317. Similarly, screw 331A and wingnut 331B can be used to secure panels 307 and 316.

Installing components 391 and 392 individually may permit installation of baffle 300 into a rack when installation of a single component baffle (e.g., baffle 100) would be difficult or not possible. For example, it may not be possible to insert a single component baffle when a rack is relatively full of equipment and/or there is equipment within 1U both above and below where a baffle is to be installed. Under these (and other circumstances) a multi-component baffle can be used.

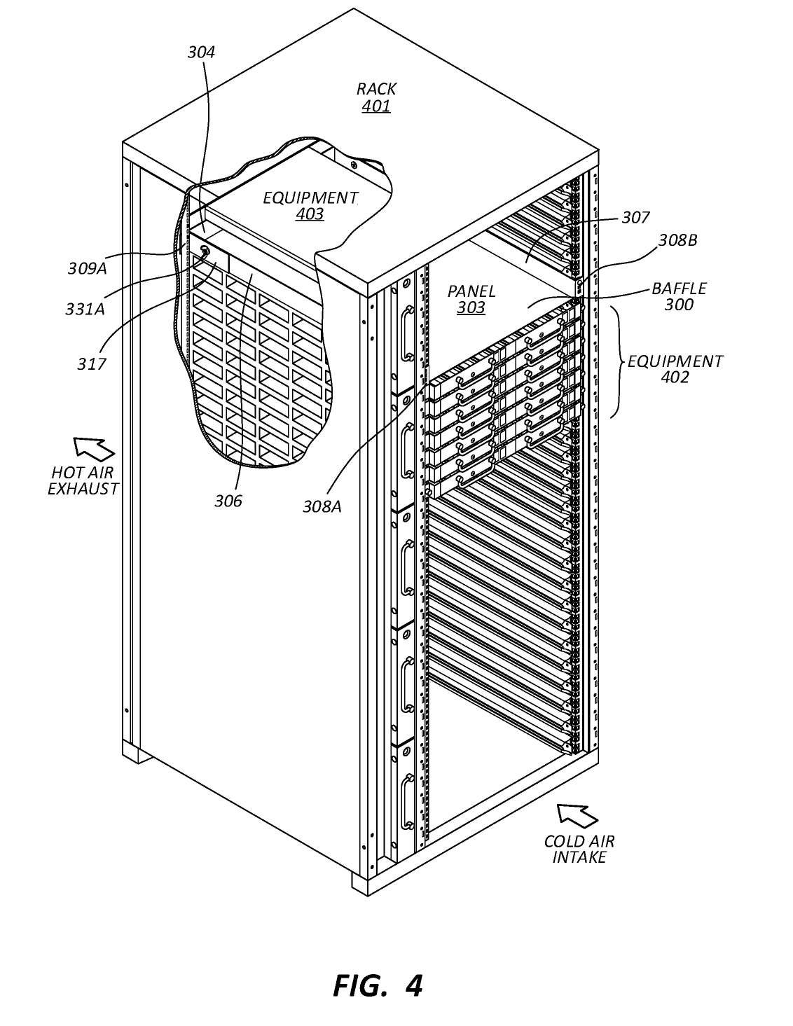

FIG. 4 illustrates an example of a baffle 300 installed in an equipment rack 401. As depicted, baffle 300, equipment 402, and equipment 403 are accommodated inside rack 401. Baffle 300 is mounted to rack 401 using attachment points 308A, 308B, 309A, and 309B. Attachment points 308A are 308B attach baffle 300 to a cold (or cool) aisle side of rack 401. Attachment points 309A and 309B attach baffle 300 to a hot (or warm) aisle side of rack 401. The height of attachment points 308A, 308B, 309A, and 309B can be 1 Rack Unit or “1U” relative to server rack rails within rack 401. Within rack 401, baffle 300 prevents air below panel 303 from entering the air intakes of equipment 403. Baffle 300 also channels air from the cold (or cool) aisle into the air intakes of equipment 403.

Components 391 and 392 can be individually installed into rack 401. Component 392 can be installed from the hot (or warm) aisle side of rack 401 and secured at attachment points 309A and 309B. Component 391 can be installed from the cold (or cool) aisle side of 401 and secured at attachment points 308A and 308B. Holes 321A and 322A and holes 321B and 322B can be aligned. Screw 332A and wingnut 332B can be used to secure panel 306 and panel 317. Screw 331A and wingnut 331B can be used to secure panel 307 and panel 316.

Additional blanking panels (not shown) can be used to block the entry of air into portions of rack 401 above equipment 403. In other aspects, equipment 403 and baffle 300 are mounted nearer to the top of rack 401. For example, baffle 300 can be mounted within the top 4 U slots of rack 201. However, these additional panels are omitted in FIG. 4 and equipment 403 and baffle 300 are positioned lower in rack 401 to provide a clear view inside rack 401.

Aspects of the invention can be used in a data center, where a plurality of racks each include one or more different computing, storage, and network devices. Baffles similar to baffles 100 and/or 300 can be used to efficiently direct air from cold (or cool) aisles within the data center to air intakes of equipment.

In one aspect, a baffle directs air flow in an equipment rack. The baffle includes a first end and a second end. The first end is configured for attachment to a first side surface of an equipment rack. The second end is configured for attachment to a second side surface of the equipment rack. The first side surface and second side surface are arranged to form an accommodation room to accommodate equipment installed into the equipment rack.

A panel spans from the first end to the second end of the equipment rack. The panel is configured to separate the airflow to equipment above the panel in the accommodation room from the airflow to equipment below the panel in the accommodation room. The first is in a closed configuration to reduce airflow out of the accommodation room at the first end. The second end is in an open configuration to permit air to flow into the accommodation room at the second end.

In another aspect, a baffle directs air flow in an equipment rack. The baffle includes a first component and a second component. The first component is configured for attachment to a first side surface of an equipment rack. The second component configured for attachment to a second side surface of the equipment rack. The first side surface and second side surface are arranged to form an accommodation room to accommodate equipment installed into the equipment rack.

The first component includes a first panel and a second panel. The first panel spans from the first side surface towards the second side surface to an intermediate location within the accommodation room. The second panel is essentially perpendicular to the first panel. The second panel is configured to block air from flowing directly out of the accommodation room at the first side surface.

The second component includes a third panel. The third panel spans from the second side surface towards the first side surface past the intermediate location to overlap with the first panel. Accordingly, the baffle is configured to separate the airflow to equipment above the first panel and the third panel in the accommodation room from the airflow to equipment below the first panel and the third panel in the accommodation room.

The present described aspects may be implemented in other specific forms without departing from its spirit or essential characteristics. The described aspects are to be considered in all respects only as illustrative and not restrictive. The scope is, therefore, indicated by the appended claims rather than by the foregoing description. All changes which come within the meaning and range of equivalency of the claims are to be embraced within their scope.

What is claimed:

1. A baffle for directing air flow in an equipment rack, the baffle comprising:
a first end, the first end configured for attachment to a first side surface of an equipment rack;
a second end, the second end configured for attachment to a second side surface of the equipment rack, the first side surface and second side surface arranged to form an accommodation room to accommodate equipment installed into the equipment rack;
a panel spanning from the first end to the second end of the equipment rack, the panel configured to separate the airflow to equipment above the panel in the accommodation room from the airflow to equipment below the panel in the accommodation room;
wherein the first end is in a closed configuration to reduce airflow out of the accommodation room at the first end; and
wherein the second end is in an open configuration to permit air to flow into the accommodation room at the second end.

2. The baffle of claim 1, wherein the first end is configured for attachment to a warm aisle side of an equipment rack; and
wherein the second end is configured for attachment to a cool aisle side of the equipment rack

3. The baffle of claim 2, wherein the first end being in a closed configuration to less easily permit airflow out of the equipment rack at the first end comprises the first end being in a closed configuration to block air from the cool aisle from passing through the accommodation room into the warm aisle without passing through equipment above the panel.

4. The baffle of claim 2, wherein the first end being in a closed configuration to less easily permit airflow out of the equipment rack at the first end comprises the first end being in a closed configuration to channel air from the cool aisle to equipment above panel.

5. The baffle of claim 2, wherein the first end being in a closed configuration to less easily permit airflow out of the equipment rack at the first end comprises a second panel at the first end, the second panel essentially perpendicular to the panel, the second panel configured to block air from flowing directly out of the accommodation room into the hot aisle.

6. The baffle of claim 2, wherein the second end being in an open configuration to more easily permit air to flow into the equipment rack at the second end comprises the second end being in an open configuration to more easily permit air to flow into the accommodate room from the cool aisle.

7. The baffle of claim 2, wherein attachment to the warm aisle side of an equipment rack comprises one or more wings configured to attach to one or more corresponding rails at the server rack.

8. A baffle for directing air flow in an equipment rack, the baffle comprising:
a first component configured for attachment to a first side surface of an equipment rack;
a second component configured for attachment to a second side surface of the equipment rack, the first side surface and second side surface arranged to form an accommodation room to accommodate equipment installed into the equipment rack;
the first component including:
a first panel spanning from the first side surface towards the second side surface to an intermediate location within the accommodation room; and
a second panel, the second panel essentially perpendicular to the first panel, the second panel configured to block air from flowing directly out of the accommodation room at the first side surface;
the second component including a third panel, the third panel spanning from the second side surface towards the first side surface past the intermediate location to overlap with the first panel; and
wherein the baffle is configured to separate the airflow to equipment above the first panel and the third panel in the accommodation room from the airflow to equipment below the first panel and the third panel in the accommodation room.

9. The baffle of claim 7, wherein the first component is configured for attachment to a warm aisle side of an equipment rack; and
wherein the second component is configured for attachment to a cool aisle side of the equipment rack.

10. The baffle of claim 9, wherein the first component being configured for attachment to a warm aisle side of an equipment rack comprises the first component being configured with one or more wings for attachment to one or more corresponding rails at the equipment rack.

11. The baffle of claim 9, wherein the second component is configured for attachment to a cool aisle side of the equipment rack comprises the second component being configured with one or more wings for attachment to one or more corresponding rails at the equipment rack.

12. The baffle of claim 7, wherein first component is mechanically coupled to the second component using one or more screws.

13. The baffle of claim 12, wherein the first component further comprises:
a first side panel including a first hole; and
a second side panel including a second hole; and
wherein the second component further comprises:
a third side panel including a third hole; and
a fourth side panel included a fourth hole.

14. The baffle of claim 13, wherein the first and second side panels are configured to channel air from a cool aisle to equipment above third panel.

15. The baffle of claim 12, wherein the first component being mechanically coupled to the second component using one or more screws comprises:
a screw passing through the first hole and the third hole to mechanically coupled the first side panel and the third side panel; and
another screw passing through the second hole and the fourth hole to mechanically coupled the second side panel and the fourth side panel.

16. The baffle of claim 12, wherein the a second panel, the second panel essentially perpendicular to the first panel, the second panel configured to block air from flowing directly out of the accommodation room at the first side surface
